(19) United States
(12) Patent Application Publication
(10) Pub. No.: US 2026/0163574 A1
(43) Pub. Date: Jun. 11, 2026

(54) PHASE-LOCKED LOOP AND OPERATING METHOD THEREOF

(71) Applicant: SK hynix Inc., Icheon-si (KR)

(72) Inventor: Jae Min SHIM, Icheon-si (KR)

(21) Appl. No.: 19/215,895

(22) Filed: May 22, 2025

(30) Foreign Application Priority Data
Dec. 11, 2024 (KR) 10-2024-0183400

(51) Int. Cl. H03L 7/095; H03L 7/081

(52) U.S. Cl. CPC H03L 7/095; H03L 7/081

(57) ABSTRACT

An operating method of a phase-locked loop, comprising: generating a control voltage according to a result of detecting a phase difference between a first clock and a second clock, generating a third clock that toggles at a frequency corresponding to a level of the control voltage, outputting one of a plurality of divided clocks divided from the third clock at a plurality of ratios as the second clock, activating a first unlock signal when the phase difference between the first and second clocks exceeds a first phase difference corresponding to a cycle of a selected divided clock among the plurality of divided clocks, activating a second unlock signal when the phase difference between the first and second clocks exceeds a second phase difference set by a plurality of delay cells, and generating a lock completion signal when both the first and second unlock signals are deactivated.

### CROSS-REFERENCE TO RELATED APPLICATION

This application claims priority under 35 U.S.C. § 119(a) to Korean Patent Application No. 10-2024-0183400, filed in the Korean Intellectual Property Office on Dec. 11, 2024, the entire contents of which are incorporated herein by reference.

### BACKGROUND

### 1. Field

Exemplary embodiments relate to a semiconductor technology, and specifically, to a phase-locked loop and an operating method thereof.

### 2. Discussion of the Related Art

A phase-locked loop (PLL) is a circuit for performing a locking operation of comparing a phase of an external clock input from an exterior with a phase of an internal clock generated therein, changing a frequency of the internal clock according to the comparison result, and synchronizing the phase of the external clock with the phase of the internal clock, and is one of basic circuits generally provided in an integrated circuit such as a semiconductor device.

When a phase difference between an external clock and an internal clock is equal to or less than a phase difference defined in advance by a plurality of delay cells, a general phase-locked loop judges that the phases of the external clock and the internal clock have been synchronized with each other and thus determines locking completion.

In such a case, a delay time definable by the plurality of delay cells, that is, a phase difference for locking reference, significantly varies as a variable dependent on PVT (process, voltage, temperature) variations. For example, a delay time definable by 16 delay cells varies from a minimum 1.44 nanoseconds (ns) to a maximum 14.92 ns due to PVT variation.

Therefore, when a phase difference used as the locking reference in the phase-locked loop varies significantly, there may occur an abnormal operation such as locking completion determination even though the phase difference between the external clock and the internal clock is not sufficiently reduced or close.

### SUMMARY

Various embodiments of the present disclosure are directed to providing a phase-locked loop that can stably apply a phase difference for locking reference regardless of PVT (process, voltage, temperature) variation and an operating method thereof.

Technical problems to be solved by the present disclosure are not limited to the aforementioned technical problems and the other technical problems not mentioned here will be clearly understood by those skilled in the art from the following description.

An aspect of an embodiment in the disclosure, a phase-locked loop may include: a phase detection unit configured to detect a phase difference between a first clock and a second clock; a voltage generation unit configured to generate a control voltage in response to an output signal of the phase detection unit; an oscillating unit configured to generate a third clock that toggles at a frequency corresponding to a level of the control voltage; a clock division unit configured to generate a plurality of divided clocks by dividing the third clock at a plurality of ratios, and any one of the plurality of divided clocks that are output is selected as the second clock; and a lock detection unit configured to generate a first unlock signal using the phase difference between the first and second clocks on the basis of a first phase difference corresponding to a cycle of a selected divided clock and to generate a second unlock signal using the phase difference between the first and second clocks on the basis of a second phase difference set by a plurality of delay cells.

An aspect of an embodiment in the disclosure, a phase-locked loop may include: a phase detection unit configured to detect a phase difference between a first clock and a second clock; a voltage generation unit configured to generate a control voltage in response to an output signal of the phase detection unit; an oscillating unit configured to generate the second clock that toggles at a frequency corresponding to a level of the control voltage; a clock division unit configured to generate a plurality of divided clocks by dividing the second clock at a plurality of ratios; and a lock detection unit configured to generate a first unlock signal using the phase difference between the first and second clocks on the basis of a first phase difference corresponding to a cycle of a selected divided clock among the plurality of divided clocks, to generate a second unlock signal using the phase difference between the first and second clocks on the basis of a second phase difference set by a plurality of delay cells, and to generate a lock completion signal in response to the first and second unlock signals.

An aspect of an embodiment in the disclosure, an operating method of a phase-locked loop, may include: generating a detection signal according to a result of detecting a phase difference between a first clock and a second clock; generating a control voltage in response to the detection signal; generating a third clock that toggles at a frequency corresponding to a level of the control voltage; generating a plurality of divided clocks by dividing the third clock at a plurality of ratios and outputting any one of the plurality of divided clocks as the second clock; activating a first unlock signal when the phase difference between the first and second clocks exceeds a first phase difference corresponding to a cycle of a selected divided clock among the plurality of divided clocks; activating a second unlock signal when the phase difference between the first and second clocks exceeds a second phase difference set by a plurality of delay cells; and generating a lock completion that signals when both the first and second unlock signals are deactivated.

The present technology can use, as a phase difference for a locking reference, a phase difference corresponding to a cycle of a clock obtained by dividing a phase of a clock generated by an oscillator of a phase-locked loop, thereby stably setting the phase difference for locking reference regardless of PVT (process, voltage, temperature) variation.

### BRIEF DESCRIPTION OF THE DRAWINGS

FIGS. 1A and 1B are block diagrams explaining examples of a phase-locked loop in accordance with embodiments of the present disclosure.

FIG. 2 is a block diagram for explaining an example of a lock detection unit of phase-locked loops illustrated in FIGS. 1A and 1B in accordance with embodiments of the present disclosure.

FIG. 3A is a block diagram for explaining an example of a clock division unit among components of a phase-locked loop illustrated in FIG. 1A in accordance with an embodiment of the present disclosure.

FIG. 3B is a block diagram for explaining an example of a clock division unit among components of a phase-locked loop illustrated in FIG. 1B in accordance with an embodiment of the present disclosure.

FIG. 4 is a block diagram for explaining an example of a lock judgment section among components of a lock detection unit illustrated in FIG. 2 in accordance with an embodiment of the present disclosure.

FIG. 5 is a circuit diagram illustrating an example of first to third signal generation sections among components of a lock detection unit illustrated in FIG. 2 and a reset signal output part among components of a lock judgment section illustrated in FIG. 4 in accordance with an embodiment of the present disclosure.

FIGS. 6A to 6C are timing diagrams for explaining an operation of a phase-locked loop in accordance with an embodiment of the present disclosure.

### DETAILED DESCRIPTION

Various embodiments of the present disclosure are described below with reference to the accompanying drawings. Elements and features of the disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware, such as for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in the disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

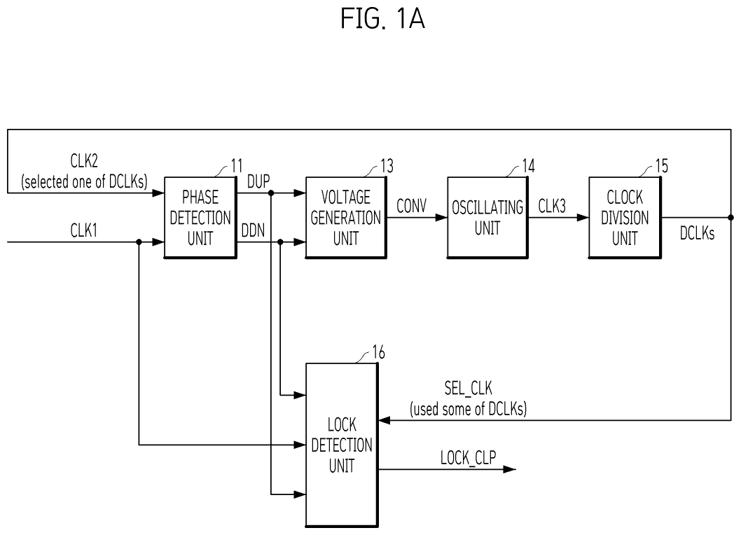

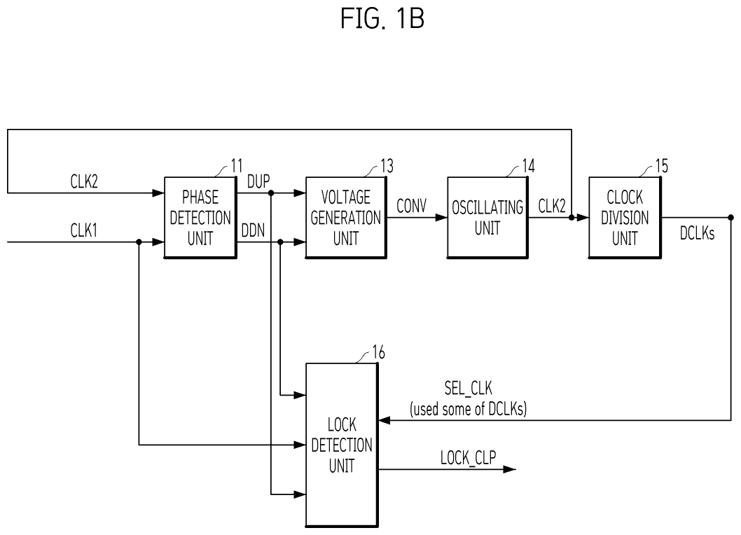

FIGS. 1A and 1B are block diagrams explaining examples of a phase-locked loop in accordance with embodiments of the present disclosure.

Referring to FIG. 1A, an example of a phase-locked loop in accordance with an embodiment of the present disclosure includes a phase detection unit 11, a voltage generation unit 13, an oscillating unit 14, a clock division unit 15, and a lock detection unit 16.

The phase detection unit 11 detects a phase difference between a first clock CLK1 and a second clock CLK2. The first clock CLK1 is a clock input from outside of the phase detection unit 11. The second clock CLK2 is any one of a plurality of divided clocks DCLKs output from the clock division unit 15.

The voltage generation unit 13 generates a control voltage CONV by performing a charge pumping operation according to signals DUP and DDN output from the phase detection unit 11.

According to an embodiment, when the phase of the second clock CLK2 is behind the phase of the first clock CLK1, the phase detection unit 11 activates a first signal DUP and deactivates a second signal DDN. In response, the voltage generation unit 13 further increases the level of the control voltage CONV beyond the current level. For example, when the level of the control voltage CONV currently being generated is 300 mV, the voltage generation unit 13 increases the level of the control voltage CONV to 320 mV in response to the activation state of the first signal DUP and the deactivation state of the second signal DDN.

According to another embodiment, when the phase of the second clock CLK2 is ahead of the phase of the first clock CLK1, the phase detection unit 11 deactivates the first signal DUP and activates the second signal DDN. In response, the voltage generation unit 13 decreases the level of the control voltage CONV beyond the current level. For example, when the level of the control voltage CONV currently being generated is 300 mV, the voltage generation unit 13 decreases the level of the control voltage CONV to 280 mV in response to the deactivation state of the first signal DUP and the activation state of the second signal DDN.

The oscillating unit 14 generates a third clock CLK3 that toggles at a frequency corresponding to the level of the control voltage CONV.

According to an embodiment, the oscillating unit 14 generates the third clock CLK3, whose toggling frequency increases in proportion to the level of the control voltage CONV.

The clock division unit 15 outputs the plurality of divided clocks DCLKs by dividing a phase of the third clock CLK3 generated by the oscillating unit 14.

According to an embodiment, the clock division unit 15 generates a 2-divided clock by dividing the phase of the third clock CLK3 by ½, a 4-divided clock by dividing the 2-divided clock by ½, an 8-divided clock by dividing the 4-divided clock by ½, a 16-divided clock by dividing the 8-divided clock by ½, a 32-divided clock by dividing the 16-divided clock by ½, a 64-divided clock by dividing the 32-divided clock by ½, a 128-divided clock by dividing the 64-divided clock by ½, and a 256-divided clock by dividing the 128-divided clock by ½. Thus, the plurality of divided clocks DCLKs generated by the clock division unit can include a total of eight divided clocks, that is, the 2-divided clock, the 4-divided clock, the 8-divided clock, the 16-divided clock, the 32-divided clock, the 64-divided clock, the 128-divided clock, and the 256-divided clock.

The clock division unit 15 selects, as the second clock CLK2, a clock divided at the highest ratio from among the plurality of divided clocks DCLKs, and outputs the second clock CLK2 to the phase detection unit 11.

According to an embodiment, the clock division unit 15 outputs the 256-divided clock, which is divided at the highest ratio from among the total of eight divided clocks, that is, the 2-divided clock, the 4-divided clock, the 8-divided clock, the 16-divided clock, the 32-divided clock, the 64-divided clock, the 128-divided clock, and the 256-divided clock, to the phase detection unit 11 as the second clock CLK2.

The example in which the clock division unit 15 generates a total of eight divided clocks by dividing an input clock by ½eight times is merely an example. Actually, the clock division unit 15 can generate any different number of divided clocks other than 8 by dividing an input clock by a ratio different from ½and/or by a different number of times than 8. However, for convenience of explanation, the following description assumes that the clock division unit 15 generates a total of eight divided clocks by dividing an input clock by ½for eight repetitions.

The lock detection unit 16 generates a first unlock signal by detecting the phase difference between the first clock CLK1 and the second clock CLK2, detected by the phase detection unit 11, on the basis of a first phase difference corresponding to a cycle of a selected divided clock SEL_CLK, selected from among the plurality of divided clocks DCLKs output from the clock division unit 15.

That is, the lock detection unit 16 determines whether to activate the first unlock signal by detecting whether the phase difference between the first clock CLK1 and the second clock CLK2 detected by the phase detection unit 11 exceeds the first phase difference corresponding to the cycle of the selected divided clock SEL_CLK.

For example, when the phase difference between the first clock CLK1 and the second clock CLK2 exceeds the first phase difference corresponding to the cycle of the selected divided clock SEL_CLK, the lock detection unit 16 may activate the first unlock signal. When the phase difference between the first clock CLK1 and the second clock CLK2 is equal to or less than the first phase difference corresponding to the cycle of the selected divided clock SEL_CLK, the lock detection unit 16 may not activate the first unlock signal.

Therefore, the lock detection unit 16 sets the cycle of the selected divided clock SEL_CLK corresponding to the first phase difference in response to some of the plurality of divided clocks DCLKs output from the clock division unit 15.

According to an embodiment, the lock detection unit 16 sets the cycle of the selected divided clock SEL_CLK corresponding to the first phase difference in response to an inversion clock (hereinafter, referred to as a selected divided inversion clock) of the selected divided clock SEL_CLK and a reference divided clock, which is divided at a division ratio twice higher than the selected divided clock. That is, the lock detection unit 16 inverts and recognizes the cycle of the selected divided clock SEL_CLK synchronized with an activation duration of the reference divided clock and recognizes, as a deactivation state, the cycle of the selected divided clock SEL_CLK synchronized with a deactivation duration of the reference divided clock. Thus, the lock detection unit 16 sets an edge, at which the reference divided clock and the selected divided inversion clock simultaneously transition from an activation state to a deactivation state, as a start time point of the cycle of the selected divided clock SEL_CLK corresponding to the time point of the first phase difference. Accordingly, the lock detection unit 16 sets the reference divided clock to be maintained in a deactivation state for one cycle of the selected divided clock SEL_CLK corresponding to the interval of the first phase difference.

In such a case, the second clock CLK2, the selected divided clock SEL_CLK, and the reference divided clock generated by the clock division unit 15 are each in a synchronized state. That is, PVT (process, voltage, temperature) variation occurring in the phase-locked loop is equally applied to the second clock CLK2, the selected divided clock SEL_CLK, and the reference divided clock, respectively.

Accordingly, when an edge at which the first clock CLK1 transitions from a deactivation state to an activation state is ahead of the time point of the first phase difference, the lock detection unit 16 detects that the phase difference between the first clock CLK1 and the second clock CLK2 exceeds the first phase difference. When the edge at which the first clock CLK1 transitions from the deactivation state to the activation state is equal to or behind the time point of the first phase difference, the lock detection unit 16 detects that the phase difference between the first clock CLK1 and the second clock CLK2 is equal to or less than the first phase difference.

For example, the lock detection unit 16 may select, as the selected divided clock SEL_CLK, the 16-divided clock from among the eight divided clocks output from the clock division unit 15, that is, from among the 2-divided clock, the 4-divided clock, the 8-divided clock, the 16-divided clock, the 32-divided clock, the 64-divided clock, the 128-divided clock, and the 256-divided clock. In addition, the lock detection unit 16 may select the 32-divided clock as the reference divided clock, thereby setting the first phase difference. That is, the lock detection unit 16 may set the first phase difference in response to the inversion clock of the 16-divided clock (hereinafter, referred to as a 16-divided inversion clock) and the 32-divided clock. That is, the lock detection unit 16 may set an edge, at which the 32-divided clock and the 16-divided inversion clock simultaneously transition from an activation state to a deactivation state, as the time point of the first phase difference. In addition, the lock detection unit 16 may set a duration, in which the 32-divided clock is in a deactivation state, that is, a duration corresponding to one cycle of the 16-divided inversion clock, as the interval of the first phase difference.

In addition, the lock detection unit 16 generates a second unlock signal by detecting the phase difference between the first clock CLK1 and the second clock CLK2, which is detected by the phase detection unit 11 on the basis of the second phase difference set by the plurality of delay cells.

That is, the lock detection unit 16 determines whether to activate the second unlock signal by detecting whether the phase difference between the first clock CLK1 and the second clock CLK2 detected by the phase detection unit 11 exceeds the second phase difference set by the plurality of delay cells.

For example, when the phase difference between the first clock CLK1 and the second clock CLK2 exceeds the second phase difference set by the plurality of delay cells, the lock detection unit 16 may activate the second unlock signal. When the phase difference between the first clock CLK1 and the second clock CLK2 is equal to or less than the second phase difference set by the plurality of delay cells, the lock detection unit 16 may not activate the second unlock signal.

In addition, the lock detection unit 16 determines whether the phases of the first clock CLK1 and the second clock CLK2 have been synchronized, that is, whether the lock has been completed, in response to the first unlock signal and the second unlock signal. The lock detection unit 16 activates a lock completion signal LOCK_CLP when it judges that the phases of the first clock CLK1 and the second clock CLK2 have been synchronized and thus the lock completion is completed.

According to an embodiment, the lock detection unit 16 activates the lock completion signal LOCK_CLP by determining that the phases of the first clock CLK1 and the second clock CLK2 have been synchronized, in response to both the first unlock signal and the second unlock signal being in a deactivation state. When any one of the first unlock signal and the second unlock signal is in an activation state, the lock detection unit 16 does not activate the lock completion signal LOCK_CLP because the phases of the first clock CLK1 and the second clock CLK2 have not been synchronized.

In addition, the lock detection unit 16 determines whether the phases of the first clock CLK1 and the second clock CLK2 have been synchronized, that is, whether the lock has been completed, in response to the first unlock signal, the second unlock signal, and the first clock CLK1. When judging that the phases of the first clock CLK1 and the second clock CLK2 have been synchronized and determining that the lock has been completed, the lock detection unit 16 activates the lock completion signal LOCK_CLP.

According to an embodiment, the lock detection unit 16 determines that the phases of the first clock CLK1 and the second clock CLK2 have been synchronized, in response to the first unlock signal and the second unlock signal both maintaining a deactivation state while the first clock CLK1 toggles a set number of times, and activates the lock completion signal LOCK_CLP. On the other hand, the lock detection unit 16 determines that the phases of the first clock CLK1 and the second clock CLK2 have not been synchronized when any one of the first unlock signal and the second unlock signal is activated while the first clock CLK1 toggles a set number of times, and may not activate the lock completion signal LOCK_CLP.

Referring to FIG. 1B, another example of a phase-locked loop in accordance with an embodiment of the present disclosure includes a phase detection unit 11, a voltage generation unit 13, an oscillating unit 14, a clock division unit 15, and a lock detection unit 16.

Compared to the configuration of the aforementioned phase-locked loop illustrated in FIG. 1A, while the reference numerals are the same, there are some differences in configuration and operation, but such differences are immaterial and most of the configuration and operation are substantially the same. Accordingly, substantially similar structures and operations will not be repeated, and the following description is based on the differences in operation from the phase-locked loop illustrated in FIG. 1A.

Referring to FIG. 1B, the phase detection unit 11 detects a phase difference between a first clock CLK1 and a second clock CLK2. The first clock CLK1 is a clock input from outside of the phase detection unit 11. The second clock CLK2 is an internal clock generated and fed back by the oscillating unit 14.

The voltage generation unit 13 generates a control voltage CONV by performing a charge pumping operation according to output signals DUP and DDN of the phase detection unit 11.

The oscillating unit 14 generates the second clock CLK2, which toggles at a frequency corresponding to the level of the control voltage CONV.

The clock division unit 15 outputs a plurality of divided clocks DCLKs by dividing a phase of the second clock CLK2 generated by the oscillating unit 14.

The lock detection unit 16 generates a first unlock signal by detecting the phase difference between the first clock CLK1 and the second clock CLK2, which is detected by the phase detection unit 11, when comparing a first phase difference corresponding to the cycle of a selected divided clock SEL_CLK output from the clock division unit 15.

In addition, the lock detection unit 16 generates a second unlock signal by detecting the phase difference between the first clock CLK1 and the second clock CLK2 compared to the second phase difference set by the plurality of delay cells.

In addition, the lock detection unit 16 determines whether the phases of the first clock CLK1 and the second clock CLK2 have been synchronized, that is, whether the lock has been completed, in response to the first unlock signal and the second unlock signal. The lock detection unit 16 activates a lock completion signal LOCK_CLP when the phases of the first clock CLK1 and the second clock CLK2 are adjudged to be synchronized and thus determines lock completion.

In summary, in FIG. 1B the second clock CLK2 generated by the oscillating unit 14 is directly transmitted to the phase detection unit 11, but in FIG. 1A, the third clock CLK3 generated by the oscillating unit 14 is divided into the plurality of divided clocks DCLKs through the clock division unit 15, and then any one of the plurality of divided clocks DCLKs is transmitted to the phase detection unit 11 as the second clock CLK2.

Other than this difference, the remaining configuration and operation are substantially the same between the phase-locked loop illustrated in FIG. 1A and the phase-locked loop illustrated in FIG. 1B. Accordingly, a detailed description of the phase-locked loop illustrated in FIG. 1B incorporates the description of the phase-locked loop illustrated in FIG. 1A.

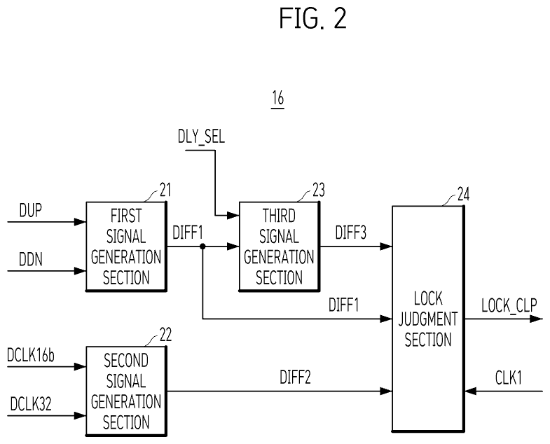

FIG. 2 is a block diagram for explaining an example of a lock detection unit of phase-locked loops illustrated in FIGS. 1A and 1B in accordance with embodiments of the present disclosure.

Referring to FIG. 2, among the components of the phase-locked loops in accordance with embodiments of the present disclosure illustrated in FIGS. 1A and 1B, a lock detection unit 16 includes a first signal generation section 21, a second signal generation section 22, a third signal generation section 23, and a lock judgment section 24.

The first signal generation section 21 generates a first difference signal DIFF1, in which a length of an activation duration is adjusted, in response to the output signals DUP and DDN of the phase detection unit 11, which indicate the phase difference between the first clock CLK1 and the second clock CLK2.

According to an embodiment, when the phase of the second clock CLK2 is behind the phase of the first clock CLK1, the phase detection unit 11 activates the first signal DUP and deactivates the second signal DDN for a duration in which the phase of the first clock CLK1 is ahead of the phase of the second clock CLK2. In addition, the first signal generation section 21 generates the first difference signal DIFF1, in which the length of the activation duration is adjusted, in response to the activation duration of the first signal DUP or the activation duration of the second signal DDN. Accordingly, when the phase of the second clock CLK2 is behind the phase of the first clock CLK1, the first signal generation section 21 adjusts the length of the activation duration of the first difference signal DIFF1 in response to the activation duration of the first signal DUP.

According to another embodiment, when the phase of the second clock CLK2 is ahead of the phase of the first clock CLK1, the phase detection unit 11 deactivates the first signal DUP and activates the second signal DDN for a duration in which the phase of the second clock CLK2 is ahead of the phase of the first clock CLK1. In addition, the first signal generation section 21 generates the first difference signal DIFF1, in which the length of the activation duration is adjusted, in response to the activation duration of the first signal DUP or the activation duration of the second signal DDN. Accordingly, when the phase of the second clock CLK2 is ahead of the phase of the first clock CLK1, the first signal generation section 21 adjusts the length of the activation duration of the first difference signal DIFF1 in response to the activation duration of the second signal DDN.

The second signal generation section 22 generates a second difference signal DIFF2, in which a time point of a deactivation duration is adjusted, in response to the inversion clock of a selected divided clock SEL_CLK, from among a plurality of divided clocks DCLKs) and a reference divided clock divided at a division ratio twice higher than that of the selected divided clock SEL_CLK. An operation of adjusting the time point of the deactivation duration of the second difference signal DIFF2 means an operation described with reference to FIGS. 1A and 1B in which the lock detection unit 16 sets the cycle of the selected divided clock SEL_CLK corresponding to the first phase difference in response to some of the plurality of divided clocks DCLKs.

That is, the second signal generation section 22 inverts the cycle of the selected divided clock SEL_CLK synchronized with the activation duration of the reference divided clock; reflects the inversion result in the second difference signal DIFF2; and reflects the cycle of the selected divided clock SEL_CLK synchronized with the deactivation duration of the reference divided clock in the second difference signal DIFF2 in the deactivation state. Thus, the second signal generation section 22 sets the start time point of the deactivation duration of the second difference signal DIFF2 as the start time point of the cycle of the selected divided clock SEL_CLK corresponding to the first phase difference. Accordingly, the second signal generation section 22 sets the second difference signal DIFF2 to maintain the deactivation state for one cycle of the selected divided clock SEL_CLK corresponding to the interval of the first phase difference.

According to an embodiment, as in FIGS. 1A and 1B, the lock detection unit 16 selects a 16-divided clock from among eight divided clocks DCLKs (i.e., from among the 2-divided clock, the 4-divided clock, the 8-divided clock, the 16-divided clock, the 32-divided clock, the 64-divided clock, the 128-divided clock, and the 256-divided clock) as the selected divided clock SEL_CLK and selects the 32-divided clock as the reference divided clock. In addition, the lock detection unit 16 sets the cycle of the 16-divided clock DCLK16 corresponding to the first phase difference in response to the 32-divided clock DCLK32, which is divided at a division ratio twice higher than that of the 16-divided inversion clock DCLK16b and the 16-divided clock DCLK16.

Applying the assumptions with reference to FIGS. 1A and 1B, the configuration and operation of the second signal generation section 22 included in the lock detection unit 16 illustrated in FIG. 2 are described as follows.

Assuming that the 16-divided clock DCLK16 is selected as the selected divided clock SEL_CLK, the second signal generation section 22 generates the second difference signal DIFF2, in which the time point of the deactivation duration is adjusted, in response to the 32-divided clock DCLK32 divided at a division ratio twice higher than that of the 16-divided inversion clock DCLK16b and the 16-divided clock DCLK16.

Since each of the 16-divided clock DCLK16 and the 32-divided clock DCLK32 is a clock generated by dividing the clock input to the clock division unit 15, that is, the second clock CLK2 (see FIG. 1B) or the third clock CLK3 (see FIG. 1A), the second clock CLK2 (see FIG. 1B) or the third clock CLK3 (see FIG. 1A), the 16-divided clock DCLK16, the 16-divided inversion clock DCLK16b, and the 32-divided clock DCLK32 are clocks synchronized with one another. Accordingly, the PVT (process, voltage, temperature) variations occurring in the phase-locked loop are equally applied to the second clock CLK2 (see FIG. 1B), the third clock CLK3 (see FIG. 1A), and the selected divided clock SEL_CLK, that is, the 16-divided inversion clock DCLK16 and the 32-divided clock DCLK32, respectively.

Accordingly, the second signal generation section 22 applies the 16-divided inversion clock DCLK16b, synchronized with the activation duration of the 32-divided clock DCLK32, to the second difference signal DIFF2 without further synchronization. The cycle of the 16-divided inversion clock DCLK16b synchronized with the deactivation duration of the 32-divided clock DCLK32 are reflected in the second difference signal DIFF2 in the deactivation state, thereby setting the start time point of the deactivation duration of the second difference signal DIFF2 as the start time point of the cycle of the 16-divided clock DCLK16 corresponding to the first phase difference. Accordingly, the second signal generation section 22 sets the second difference signal DIFF2 to maintain the deactivation state for one cycle of the 16-divided inversion clock DCLK16b, which corresponds to the interval of the first phase difference.

That is, the second signal generation section 22 sets, as the start time point of the first phase difference, an edge at which the 32-divided clock DCLK32 and the 16-divided inversion clock DCLK16b transition from an activation state to a deactivation state, which is also an edge at which the deactivation duration of the second difference signal DIFF2 starts. In addition, the second signal generation section 22 sets, as the interval of the first phase difference, the deactivation duration of the 32-divided clock DCLK32. In the deactivation duration of the 32-divided clock DCLK32, the second difference signal DIFF2 is in a deactivation state, that is, the duration corresponds to one cycle of the 16-divided inversion clock DCLK16 b.

Setting the 16-divided clock DCLK16 among the plurality of divided clocks DCLKs as the selected divided clock SEL_CLK is merely an example, and a divided clock divided by a division ratio greater or smaller than 16 can also be used to generate the selected divided clock SEL_CLK.

In addition, the third signal generation section 23 outputs a third difference signal DIFF3 by delaying the first difference signal DIFF1 by a delay amount, which is set by the plurality of delay cells. That is, the first difference signal DIFF1 input to the third signal generation section 23 and the third difference signal DIFF3 generated by the third signal generation section 23 have a difference according to the delay amount set by the plurality of delay cells. A length of the delay amount set by the plurality of delay cells corresponds to the second phase difference.

In response to a delay control signal DLY_SEL, the third signal generation section 23 adjusts the delay amount set by the plurality of delay cells. That is, the third signal generation section 23 outputs the third difference signal DIFF3 by delaying the first difference signal DIFF1 through a delay amount set using at least one delay cell selected by the delay control signal DLY_SEL, from among the plurality of delay cells included in the phase-locked loop.

The lock judgment section 24 determines whether to activate the first unlock signal in response to the first difference signal DIFF1 and the second difference signal DIFF2.

That is, the lock judgment section 24 compares the start time point of the activation duration of the first difference signal DIFF1 with the start time point of the deactivation duration of the second difference signal DIFF2, and determines whether to activate the first unlock signal according to the comparison result.

According to an embodiment, when the start time point of the deactivation duration of the second difference signal DIFF2 is behind the start time point of the activation duration of the first difference signal DIFF1, the lock judgment section 24 activates the first unlock signal between the start time point of the activation duration of the first difference signal DIFF1 and the start time point of the deactivation duration of the second difference signal DIFF2. In this way, when the first unlock signal is activated, the lock judgment section 24 determines that the phase difference between the first clock CLK1 and the second clock CLK2 exceeds the first phase difference.

According to another embodiment, when the start time point of the deactivation duration of the second difference signal DIFF2 is ahead of or equal to the start time point of the activation duration of the first difference signal DIFF1, the lock judgment section 24 does not activate the first unlock signal. In this way, when the first unlock signal is not activated, the lock judgment section 24 determines that the phase difference between the first clock CLK1 and the second clock CLK2 is equal to or less than the first phase difference.

In addition, the lock judgment section 24 determines whether to activate the second unlock signal in response to the first difference signal DIFF1 and the third difference signal DIFF3.

That is, the lock judgment section 24 confirms whether the activation duration of the first difference signal DIFF1 and the activation duration of the third difference signal DIFF3 overlap each other, and determines whether to activate the second unlock signal according to the confirmation result.

According to an embodiment, when the activation duration of the first difference signal DIFF1 and the activation duration of the third difference signal DIFF3 overlap each other in excess of acceptable margins, the lock judgment section 24 activates the second unlock signal for the duration of the overlap. In this way, when the second unlock signal is activated, the lock judgment section 24 determines that the phase difference between the first clock CLK1 and the second clock CLK2 exceeds the second phase difference.

According to another embodiment, when the activation duration of the first difference signal DIFF1 and the activation duration of the third difference signal DIFF3 do not overlap each other, the lock judgment section 24 may not activate the second unlock signal. In this way, when the second unlock signal is not activated, the lock judgment section 24 determines that the phase difference between the first clock CLK1 and the second clock CLK2 is equal to or less than the second phase difference.

In addition, the lock judgment section 24 judges whether the phases of the first clock CLK1 and the second clock CLK2 have been synchronized, that is, whether the lock has been completed, by combining the activation or deactivation of the first unlock signal and the second unlock signal. In addition, the lock judgment section 24 judges whether the phases of the first clock CLK1 and the second clock CLK2 have been synchronized, that is, whether the lock has been completed, in response to the first unlock signal, the second unlock signal, and the first clock CLK1. When judging that the phases of the first clock CLK1 and the second clock CLK2 have been synchronized and thus determining lock completion, the lock detection unit 16 activates the lock completion signal LOCK_CLP.

According to an embodiment, the lock judgment section 24 generates the lock completion signal LOCK_CLP when it judges that the phases of the first clock CLK1 and the second clock CLK2 have been synchronized, in response to both the first unlock signal and the second unlock signal not being activated. On the other hand, when any one of the first unlock signal and the second unlock signal is activated, the lock judgment section 24 judges that the phases of the first clock CLK1 and the second clock CLK2 have not been synchronized and may not activate the lock completion signal LOCK_CLP.

According to another embodiment, the lock judgment section 24 judges that the phases of the first clock CLK1 and the second clock CLK2 have been synchronized, in response to neither the first unlock signal nor the second unlock signal not being activated in a duration in which the first clock CLK1 toggles a set number of times, and activates the lock completion signal LOCK_CLP. On the other hand, when any one of the first unlock signal and the second unlock signal is activated in the duration in which the first clock CLK1 toggles the set number of times, the lock judgment section 24 judges that the phases of the first clock CLK1 and the second clock CLK2 have not been synchronized and may not activate the lock completion signal LOCK_CLP.

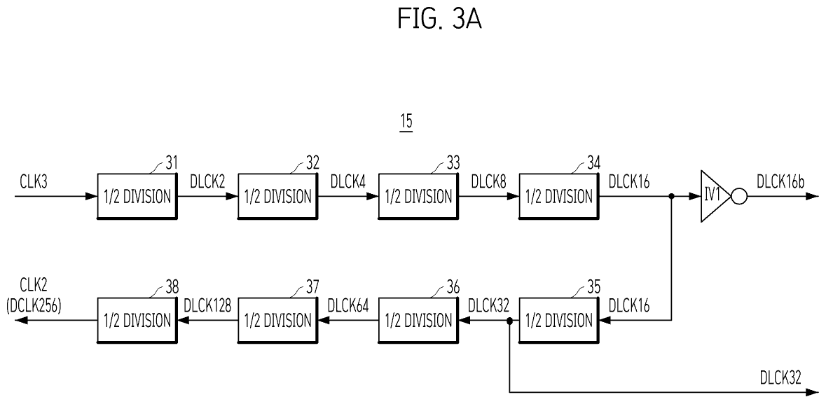

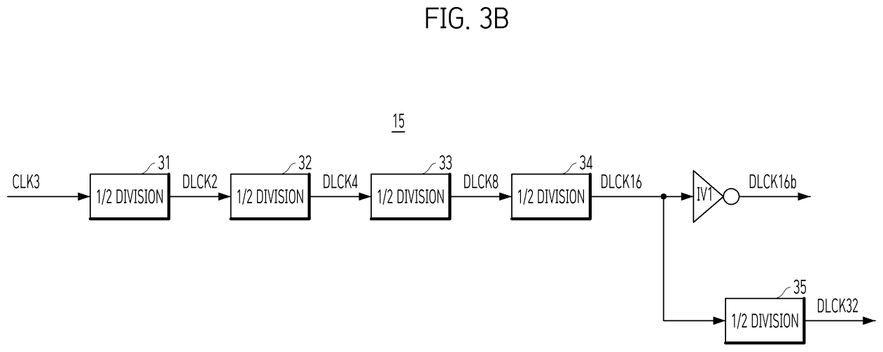

FIG. 3A is a block diagram for explaining an example of a clock division unit among components of a phase-locked loop illustrated in FIG. 1A in accordance with ab embodiment of the present disclosure.

FIG. 3B is a block diagram for explaining an example of a clock division unit among components of a phase-locked loop illustrated in FIG. 1B in accordance with an embodiment of the present disclosure.

Referring to FIG. 3A, the clock division unit 15 among the components of a phase-locked loop illustrated in FIG. 1A includes eight division circuits 31 to 38 connected in series for dividing the input clock by ½ and outputting divided clocks.

Specifically, the clock division unit 15 includes a first division circuit 31 for dividing the phase of the third clock CLK3 by ½ to generate the 2-divided clock DLCK2, a second division circuit 32 for dividing the 2-divided clock DLCK2 by ½ to generate the 4-divided clock DCLK4, a third division circuit 33 for dividing the 4-divided clock DCLK4 by ½ to generate the 8-divided clock DCLK8, a fourth division circuit 34 for dividing the 8-divide clock DCLK8 by ½ to generate the 16-divided clock DCLK16, a fifth division circuit 35 for dividing the 16-divided clock DCLK16 by ½ to generate the 32-divided clock DCLK32, a sixth division circuit 36 for dividing the 32-divided clock DCLK32 by ½ to generate the 64-divided clock, a seventh division circuit 37 for dividing the 64-divided clock DCLK64 by ½ to generate the 128-divided clock DCLK128, and an eighth division circuit 38 for dividing the 128-divided clock DCLK128 by ½ to generate the 256-divided clock DCLK256.

Referring to FIGS. 1A and 3A together, the clock division unit 15 selects the 256-divided clock DCLK256, which is a clock divided at the highest ratio from among the plurality of divided clocks DCLKs generated internally, as the second clock CLK2 and outputs the second clock CLK2 to the phase detection unit 11.

In addition, referring to FIGS. 1A and 3A together, the clock division unit 15 further includes an inverter IV1 for inverting the 16-divided clock DCLK16 to generate the 16-divided inversion clock DCLK16b. That is, the clock division unit 15 outputs the 16-divided inversion clock DCLK16b output from the inverter IV1 and the 32-divided clock DCLK32 to the second signal generation section 22 included in the lock detection unit 16.

Referring to FIG. 3B, it can be seen that the clock division unit 15 among the components of the phase-locked loop illustrated in FIG. 1B includes five division circuits 31 to 35 connected in series for dividing the input clock by ½ and outputting divided clocks.

Specifically, the clock division unit 15 includes a first division circuit 31 for dividing the phase of the third clock CLK3 by ½ to generate the 2-divided clock DLCK2, a second division circuit 32 for dividing the 2-divided clock DLCK2 by ½ to generate the 4-divided clock DCLK4, a third division circuit 33 for dividing the 4-divided clock DCLK4 by ½ to generate the 8-divided clock DCLK8, a fourth division circuit 34 for dividing the 8-divided clock DCLK8 by ½ to generate the 16-divided clock DCLK16, and a fifth division circuit 35 for dividing the 16-divided clock DCLK16 by ½ to generate the 32-divided clock DCLK32.

In addition, referring to FIGS. 1B and 3B together, the clock division unit 15 further includes an inverter IV1 for inverting the 16-divided clock DCLK16 to generate the 16-divided inversion clock DCLK16b. That is, the clock division unit 15 outputs the 16-divided inversion clock DCLK16b from the inverter IV1 and the 32-divided clock DCLK32 to the second signal generation section 22 included in the lock detection unit 16.

In summary, as described with respect to FIGS. 1A and 1B described above, there is a difference in that in FIG. 1B, the second clock CLK2 generated by the oscillating unit 14 is directly transmitted to the phase detection unit 11, but in FIG. 1A, the third clock CLK3 generated by the oscillating unit 14 is divided into the plurality of divided clocks DCLKs through the clock division unit 15 and then any one of the plurality of divided clocks DCLKs is transmitted to the phase detection unit 11 as the second clock CLK2.

Accordingly, it can be seen in FIG. 3A that the eight division circuits 31 to 38 are included in the clock division unit 15 in order to transmit the 256-divided clock DCLK256 divided at the highest ratio, among the plurality of divided clocks DCLKs, to the phase detection unit 11 as the second clock CLK2. It can also be seen in FIG. 3A that the 16-divided clock DCLK16, which is output from the fourth division circuit 34 among the eight division circuits 31 to 38 included in the clock division unit 15 in order to generate the 256-divided clock DCLK256, is set as the selected divided clock SEL_CLK and the 16-divided inversion clock DCLK16b and the 32-divided clock DCLK32 are output to the second signal generation section 22 included in the lock detection unit 16.

On the other hand, it can be seen in FIG. 3B that the five division circuits 31 to 35 are included in the clock division unit 15 in order to output the 16-divided inversion clock DCLK16 and the 32-divided clock DCLK32 to the second signal generation section 22 included in the lock detection unit 16. That is, since the clock division unit 15 illustrated in FIG. 3B is a component included for the operation of the lock detection unit 16, only the five division circuits 31 to 35 are included instead of the eight division circuits 31 to 38 as in FIG. 3A.

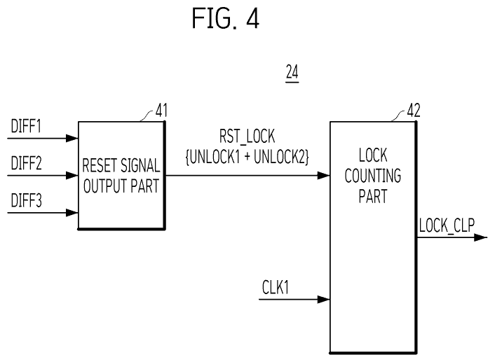

FIG. 4 is a block diagram for explaining an example of a lock judgment section among components of a lock detection unit illustrated in FIG. 2 in accordance with an embodiment of the present disclosure.

Referring to FIG. 4, among the components of a lock detection unit 16 illustrated in FIG. 2, a lock judgment section 24 includes a reset signal output part 41 and a lock counting part 42.

First, as described with reference to FIG. 2, the lock judgment section 24 determines whether to activate the first unlock signal, in response to the first difference signal DIFF1 and the second difference signal DIFF2. The lock judgment section 24 determines whether to activate the second unlock signal, in response to the first difference signal DIFF1 and the third difference signal DIFF3. In addition, the lock judgment section 24 determines whether the phases of the first clock CLK1 and the second clock CLK2 have been synchronized, that is, whether the lock has been completed, by combining the activation or deactivation of the first unlock signal and the second unlock signal.

The operation in which the lock judgment section 24 selects whether to activate each of the first unlock signal UNLOCK1 and the second unlock signal UNLOCK2 and to output a selection result is the same operation as when the reset signal output part 41 included in the lock judgment section 24 selects whether to activate a reset signal RST_LOCK and output a selection result.

Specifically, the reset signal output part 41 included in the lock judgment section 24 activates the reset signal RST_LOCK in a duration in which any one of the first unlock signal UNLOCK1 and the second unlock signal UNLOCK2 is activated.

In addition, the reset signal output part 41 activates the reset signal RST_LOCK in a duration, in which the first unlock signal is activated, in response to the first difference signal DIFF1 and the second difference signal DIFF2.

That is, the reset signal output part 41 compares the start time point of the activation duration of the first difference signal DIFF1 and the start time point of the deactivation duration of the second difference signal DIFF2, and determines whether to activate the reset signal RST_LOCK according to the comparison result.

According to an embodiment, when the start time point of the deactivation duration of the second difference signal DIFF2 is behind the start time point of the activation duration of the first difference signal DIFF1, the reset signal output part 41 activates the reset signal RST_LOCK between the start time point of the activation duration of the first difference signal DIFF1 and the start time point of the deactivation duration of the second difference signal DIFF2.

According to another embodiment, when the start time point of the deactivation duration of the second difference signal DIFF2 is ahead of or equal to the start time point of the activation duration of the first difference signal DIFF1, the reset signal output part 41 may not activate the reset signal RST_LOCK.

In response to the first difference signal DIFF1 and the third difference signal DIFF3, the reset signal output part 41 activates the reset signal RST_LOCK in the duration in which the second unlock signal is activated.

That is, the reset signal output part 41 confirms whether the activation duration of the first difference signal DIFF1 and the activation duration of the third difference signal DIFF3 overlap each other, and determines whether to activate the reset signal RST_LOCK according to the confirmation result.

According to an embodiment, when the activation duration of the first difference signal DIFF1 and the activation duration of the third difference signal DIFF3 overlap each other, the reset signal output part 41 activates the reset signal RST_LOCK in the overlapping duration.

According to another embodiment, when the activation duration of the first difference signal DIFF1 and the activation duration of the third difference signal DIFF3 do not overlap each other, the reset signal output part 41 may not activate the reset signal RST_LOCK.

In addition, the lock counting part 42 counts the number of toggling of the first clock CLK1, determines that the lock has been completed when the counted value reaches a set number of times, and activates the lock completion signal LOCK_CLP. In addition, the lock counting part 42 initializes the counted value in response to the reset signal RST_LOCK being activated.

That is, when the reset signal RST_LOCK is not activated while the lock counting part 42 counts the toggling of the first clock CLK1 for the set number of times, the lock counting part 42 determines that the phases of the first clock CLK1 and the second clock CLK2 have been synchronized and activates the lock completion signal LOCK_CLP.

In addition, the lock counting part 42 initializes the counted value in response to the reset signal RST_LOCK being activated before counting the toggling of the first clock CLK1 by the set number of times. In such a case, since the counted value has not reached the set value, the lock counting part 42 may not activate the lock completion signal LOCK_CLP.

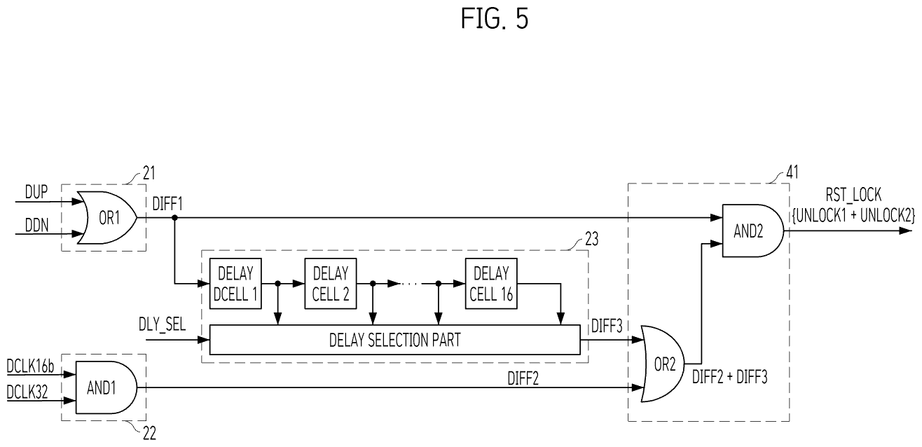

FIG. 5 is a circuit diagram illustrating an example of the first to third signal generation sections among components of a lock detection unit illustrated in FIG. 2 and a reset signal output part among components of a lock judgment section illustrated in FIG. 4 in accordance with an embodiment of the present disclosure.

FIG. 5 illustrates an example of a detailed circuit of each of a first signal generation section 21, a second signal generation section 22, and a third signal generation section 23 among components of a lock detection unit 16 illustrated in FIG. 2, and an example of a detailed circuit of a reset signal output part 41 among the components of a lock judgment section 24 illustrated in FIG. 4.

The first signal generation section 21 included in the lock detection unit 16 includes a first OR gate OR1 that receives the output signals DUP and DDN of the phase detection unit 11 indicating the phase difference between the first clock CLK1 and the second clock CLK2, performs an OR operation, and outputs the first difference signal DIFF1.

According to an embodiment, when the phase of the second clock CLK2 is behind the phase of the first clock CLK1, the phase detection unit 11 activates the first signal DUP and deactivates the second signal DDN for a duration in which the phase of the first clock CLK1 is ahead of the phase of the second clock CLK2. Accordingly, when the phase of the second clock CLK2 is behind the phase of the first clock CLK1, the first OR gate OR1 included in the first signal generation section 21 outputs the first difference signal DIFF1 having a length of the activation duration corresponding to the length of the activation duration of the first signal DUP.

According to another embodiment, when the phase of the second clock CLK2 is ahead of the phase of the first clock CLK1, the phase detection unit 11 deactivates the first signal DUP and activates the second signal DDN for a duration in which the phase of the second clock CLK2 is ahead of the phase of the first clock CLK1. Accordingly, when the phase of the second clock CLK2 is ahead of the phase of the first clock CLK1, the first OR gate OR1 included in the first signal generation section 21 outputs the first difference signal DIFF1 having a length of the activation duration corresponding to the length of the activation duration of the second signal DDN.

The second signal generation section 22 included in the lock detection unit 16 includes a first AND gate AND1 that receives the 16-divided inversion clock DCLK16b and the 32-divided clock DCLK32, performs an AND operation, and outputs the second difference signal DIFF2.

According to an embodiment, the first AND gate AND1 included in the second signal generation section 22 outputs the 16-divided inversion clock DCLK16b as the second difference signal DIFF2, as it is in a duration in which the 32-divided clock DCLK32 is activated to logic high. Accordingly, the transition time point when the 32-divided clock DCLK32 is deactivated to logic low from the state of being activated to logic high, the transition time point when the 16-divided inversion clock DCLK16b is deactivated to logic low from the state of being activated to logic high, and the transition time point when the second difference signal DIFF2 is deactivated to logic low from the state of being activated to logic high, are all synchronized to each other.

In a duration in which the 32-divided clock DCLK32 is deactivated to logic low, the first AND gate AND1 included in the second signal generation section 22 maintains the second difference signal DIFF2 in the state of being deactivated to logic low regardless of whether the 16-divided inversion clock DCLK16b is activated. Accordingly, the second difference signal DIFF2 maintains the deactivation state for one cycle of the 16-divided inversion clock DCLK16b from the transition time point when the 32-divided clock DCLK32 is deactivated to logic low from the state of being activated to logic high.

In such a case, the first phase difference is set in response to one cycle of the 16-divided inversion clock DCLK16b, that is, one cycle of the 16-divided clock DCLK16. Accordingly, the second difference signal DIFF2 output from the first AND gate AND1 maintains the deactivation state by an interval corresponding to the first phase difference from the time point when the 32-divided clock DCLK32 is deactivated from the activation state.

The third signal generation section 23 included in the lock detection unit 16 includes a plurality of delay cells and a delay selection part for outputting the third difference signal DIFF3 by delaying the first difference signal DIFF1 by a delay amount corresponding to the second phase difference. That is, the first difference signal DIFF1 input to the third signal generation section 23 and the third difference signal DIFF3 generated by the third signal generation section 23 are set to have a difference by the delay amount corresponding to the second phase difference through a delay cell that is selected by the delay selection part from among a plurality of delay cells.

For example, as illustrated in the drawing, the third signal generation section 23 includes 16 delay cells, and the operation of the delay selection part that selects at least one of the 16 delay cells in response to the delay control signal DLY_SEL causes the first difference signal DIFF1 input to the third signal generation section 23 and the third difference signal DIFF3 output from the third signal generation section 23 to have a difference by the delay amount corresponding to the second phase difference.

The reset signal output part 41 included in the lock judgment section 24 includes a second OR gate OR2 and a second AND gate AND2.

Specifically, the second OR gate OR2 included in the reset signal output part 41 outputs a signal DIFF2+DIFF3, which is obtained from the second difference signal DIFF2 and the third difference signal DIFF3 as inputs to the second OR gate OR2. That is, the second OR gate OR2 activates and outputs the signal DIFF2+DIFF3 output in the duration in which the second difference signal DIFF2 is activated to logic high or the duration in which the third difference signal DIFF3 is activated to logic high. In addition, the second OR gate OR2 deactivates, to logic low, the signal DIFF2+DIFF3 output in the duration in which both the second difference signal DIFF2 and the third difference signal DIFF3 are deactivated to logic low, and outputs the deactivated signal.

The second AND gate AND2 included in the reset signal output part 41 performs an AND operation on the first difference signal DIFF1 and the output signal DIFF2+DIFF3, which is the result of the second OR gate OR2, and outputs the reset signal RST_LOCK.

In such a case, the second difference signal DIFF2 maintains the logic low deactivation state for the duration corresponding to the first phase difference from the transition time point from the logic high activation state to the logic low deactivation state.

In addition, the duration, from the transition time point of the first difference signal DIFF1 from the logic low deactivation state to the logic high activation state to the transition time point of the third difference signal DIFF3 from the logic low deactivation state to the logic high activation state, corresponds to the second phase difference.

That is, the duration corresponding to the first phase difference is implemented through the deactivation state of the second difference signal DIFF2, and the duration corresponding to the second phase difference is implemented through the deactivation state of the third difference signal DIFF3.

In addition, the output signal DIFF2+DIFF3 of the second OR gate OR2 is deactivated to logic low only when both the second difference signal DIFF2 and the third difference signal DIFF3 are deactivated to logic low, and is activated to logic high when any one of the second difference signal DIFF2 and the third difference signal DIFF3 is activated to logic high. In addition, the duration in which the first difference signal DIFF1 is activated to logic high corresponds to the phase difference between the first clock CLK1 and the second clock CLK2.

Accordingly, the presence of a duration, in which the reset signal RST_LOCK generated by the second AND gate AND2 that performs an AND operation on the output signal DIFF2+DIFF3 of the second OR gate OR2 and the first difference signal DIFF1 is activated to logic high, means that the phase difference between the first clock CLK1 and the second clock CLK2 exceeds any one of the first phase difference or the second phase difference.

On the other hand, the absence of a duration, in which the reset signal RST_LOCK generated by the second AND gate AND2 that performs an AND operation on the output signal DIFF2+DIFF3 of the second OR gate OR2 and the first difference signal DIFF1 is activated to logic high, means that the phase difference between the first clock CLK1 and the second clock CLK2 is equal to or less than any of the first phase difference or the second phase difference.

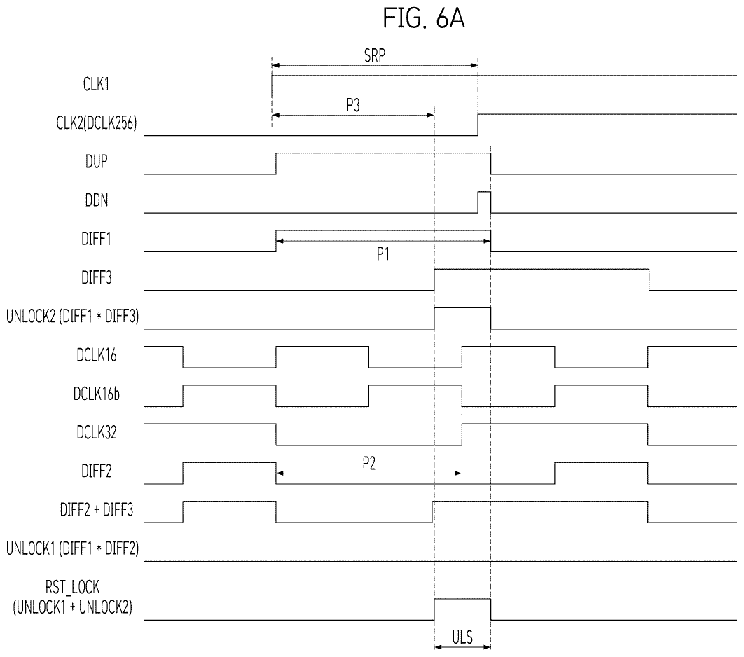

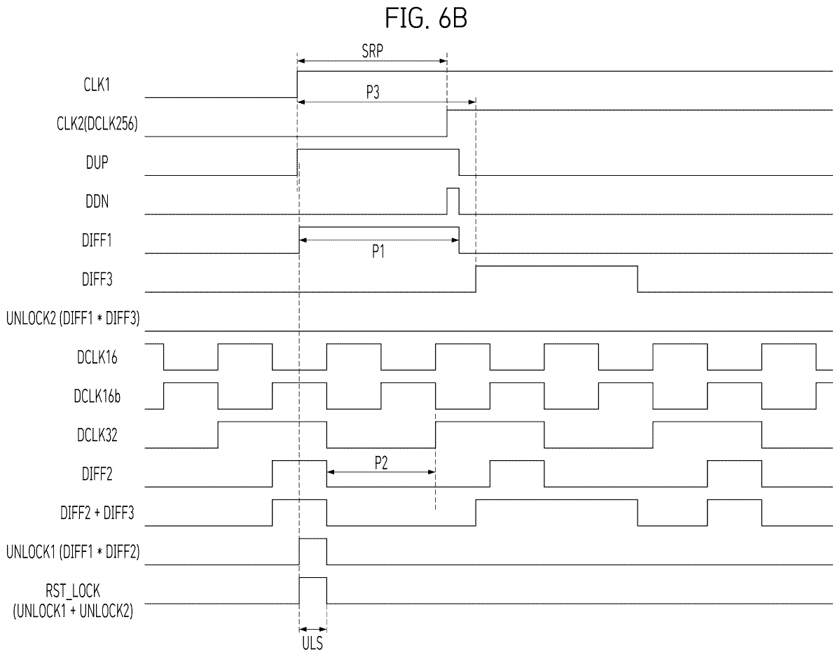

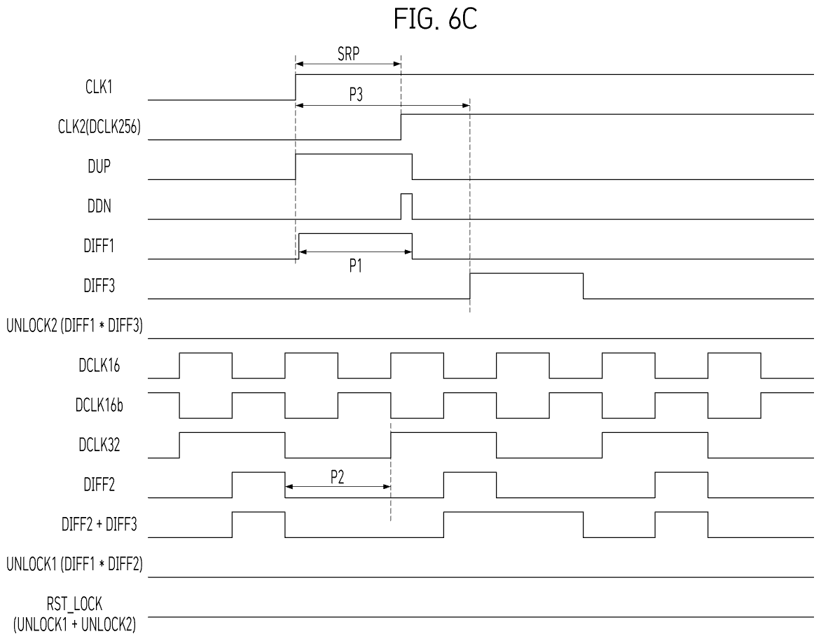

FIGS. 6A to 6C are timing diagrams for explaining an operation of a phase-locked loop in accordance with an embodiment of the present disclosure.

FIGS. 6A to 6C illustrate operations for a phase-locked loop illustrated in FIG. 1A in accordance with the embodiment of the present disclosure. That is, the second clock CLK2 fed back in the phase-locked loop is a 256-divided clock DCLK256 generated by dividing a third clock CLK3 (not illustrated) by a ratio of 256. In addition, the 256-divided clock DCLK256 generated by dividing the third clock CLK3 by a ratio of 256, a 16-divided clock DCLK16 generated by dividing the third clock CLK3 by a ratio of 16, and a 32-divided clock DCLK32 generated by dividing the third clock CLK3 by a ratio of 32 are synchronized with one another, so that the PVT variations occurring in the phase-locked loop are applied equally.

Specifically, FIG. 6A illustrates a very large phase difference SRP between the first clock CLK1 and the second clock CLK2 in an initial operation duration of the phase-locked loop.

In particular, FIG. 6A illustrates a state in which the operation of the clock division unit 15 is not stabilized in the initial operation duration of the phase-locked loop and thus the cycle of the 16-divided clock DCLK16 is unstable and long. Therefore, FIG. 6A illustrates a state in which the first phase difference P2, corresponding to one cycle of the 16-divided clock DCLK16, is abnormally long in an initial state for a locking operation compared to a target state.

In this way, even in a state in which the first phase difference P2 is abnormally long because the operation of the clock division unit 15 is not stabilized in the initial operation duration of the phase-locked loop, the phase-locked loop in accordance with the embodiment of the present disclosure performs an operation of activating the reset signal RST_LOCK to logic high when the activation duration of the third difference signal DIFF3 corresponding to the second phase difference P3 overlaps the activation duration of the first difference signal DIFF1.

Specifically, the interval from the transition time point of the first clock CLK1 from logic low to logic high to the transition time point of the second clock CLK2 from logic low to logic high is the phase difference SRP between the first clock CLK1 and the second clock CLK2.

The phase detection unit 11 ascertains that the phase of the first clock CLK1 is ahead of the phase of the second clock CLK2 because the second clock CLK2 is in a logic low state at the transition time point when the first clock CLK1 changes from logic low to logic high. Accordingly, the phase detection unit 11 causes the first signal DUP to transition from logic low to logic high in response to the transition of the first clock CLK1 from logic low to logic high, causes the second signal DDN to toggle to logic high for a set time in response to the transition of the second clock CLK2 from logic low to logic high, and causes the first signal DUP to transition from logic high to logic low in response to the toggling of the second signal DDN to logic high.

Accordingly, the first signal generation section 21 included in the lock detection unit 16 causes the first difference signal DIFF1 to transition from logic low to logic high at the transition time point of the first signal DUP from logic low to logic high, and causes the first difference signal DIFF1 to transition from logic high to logic low at the transition time point of the first signal DUP from logic high to logic low. That is, it can be seen that the duration in which the first difference signal DIFF1 is activated to logic high covers the phase difference between the first clock CLK1 and the second clock CLK2.D

It can be seen that the length of the duration in which the first signal DUP and the first difference signal DIFF1 are activated to logic high is slightly longer than the phase difference between the first clock CLK1 and the second clock CLK2, that is, longer by the length corresponding to the toggling of the second signal DDN. This is the time required in a process of processing the phase difference between the first clock CLK1 and the second clock CLK2, that is, the activation duration of the first signal DUP and the first difference signal DIFF1. Because this is a very small interval compared to the phase difference used as the locking reference of the phase-locked loop, it can be ignored in the actual operation of the phase-locked loop.

The second signal generation section 22 included in the lock detection unit 16 outputs the 16-divided inversion clock DCLK16b as the second difference signal DIFF2 as it is in the duration in which the 32-divided clock DCLK32 is activated to logic high. Accordingly, the transition time point when the 32-divided clock DCLK32 is deactivated to logic low from the state of being activated to logic high, the transition time point when the 16-divided inversion clock DCLK16b is deactivated to logic low from the state of being activated to logic high, and the transition time point when the second difference signal DIFF2 is deactivated to logic low from the state of being activated to logic high (e.g., at the start of the first phase difference P2 in FIG. 6A) are all synchronized.

In the duration in which the 32-divided clock DCLK32 is deactivated to logic low, the second signal generation section 22 maintains the second difference signal DIFF2 in the state of being deactivated to logic low regardless of whether the 16-divided inversion clock DCLK16b is activated. Accordingly, the second difference signal DIFF2 maintains the deactivation state for at least one cycle of the 16-divided inversion clock DCLK16b from the transition time point when the 32-divided clock DCLK32 is deactivated from logic low from the state of being activated to logic high.

In such a case, the first phase difference P2 is set in response to one cycle of the 16-divided inversion clock DCLK16b, that is, at least one cycle of the 16-divided clock DCLK16. Accordingly, the second difference signal DIFF2 output from the second signal generation section 22 maintains the deactivation state during an interval corresponding to the first phase difference P2 from the time point when it is deactivated from the activation state.

As described above, the graph illustrated in FIG. 6A illustrates a state in which the cycle of the 16-divided clock DCLK16 is unstably long due to an unstable operation of the clock division unit 15 in the initial operation duration of the phase-locked loop, and the first phase difference P2 corresponding to one cycle of the 16-divided clock DCLK16 is abnormally long compared to a target state for a locking operation. Therefore, the deactivation state of the second difference signal DIFF2 corresponding to the first phase difference P2 is slightly ahead of the activation duration of the first difference signal DIFF1. That is, the time point when the second difference signal DIFF2 is deactivated from the activation state is ahead of the time point when the first difference signal DIFF1 is activated from the deactivation state.

Accordingly, the first unlock signal UNLOCK1, which is activated in response to the activation of the second difference signal DIFF2 in the activation duration of the first difference signal DIFF1, is not activated to logic high and continuously maintains a logic low state.

In addition, the third signal generation section 23 included in the lock detection unit 16 outputs the third difference signal DIFF3 by delaying the first difference signal DIFF1 by the delay amount corresponding to the second phase difference P3.

In such a case, as described above, since the graph illustrated in FIG. 6A shows that the phase difference SRP between the first clock CLK1 and the second clock CLK2 in the initial operation duration of the phase-locked loop is very large, that is, the length of the duration in which the first difference signal DIFF1 is activated to logic high is very long, it can be seen that the duration in which the first difference signal DIFF1 is activated to logic high and the duration in which the third difference signal DIFF3 is activated to logic high overlap each other for a certain duration ULS.

Accordingly, it can be seen that the second unlock signal UNLOCK2, which is activated in response to the activation of the third difference signal DIFF3 in the activation duration of the first difference signal DIFF1, is activated to logic high for the duration ULS.

In summary, in the graph illustrated in FIG. 6A, the first unlock signal UNLOCK1 is not activated to logic high and continuously maintains a logic low state, but the second unlock signal UNLOCK2 is activated to logic high for a duration ULS. Accordingly, the reset signal RST_LOCK is also activated to logic high in response to the activation of the second unlock signal UNLOCK2 to logic high for the duration ULS.

In this way, since the reset signal RST_LOCK is activated to logic high, the phase-locked loop determines that the phases of the first clock CLK1 and the second clock CLK2 have not been synchronized.

For reference, since the delay amount corresponding to the second phase difference P3 set by the third signal generation section 23 is set by the plurality of delay cells, the delay amount varies due to the influence of PVT variation. However, since large PVT variation is less likely to occur after the operation of locking the phases of the first clock CLK1 and the second clock CLK2 is performed once in the phase-locked loop, the delay amount corresponding to the second phase difference P3 continuously maintains an initially set amount while the locking operation of the phase-locked loop is performed once.

FIG. 6B illustrates a phase-locked loop that has progressed beyond the state described with reference to FIG. 6A, where the phase difference SRP between the first clock CLK1 and the second clock CLK2 has been significantly narrowed compared to the graph of FIG. 6A.

In particular, FIG. 6B illustrates that because the operation of the phase-locked loop has sufficiently progressed, the operation of the clock division unit 15 has been stabilized, and accordingly, the first phase difference P2 corresponding to one cycle of the 16-divided clock DCLK16 is in a target state for locking.

In addition, FIG. 6B illustrates a state in which due to the PVT variation occurring in the phase-locked loop, the length of the second phase difference P3 is longer than the target state for locking and thus is longer than the length of the first phase difference P2.

In this way, even when the length of the second phase difference P3 is longer than the target state for locking due to the PVT variation occurring in the phase-locked loop, the phase-locked loop in accordance with an embodiment of the present disclosure performs an operation of activating the reset signal RST_LOCK to logic high when the duration in which the second difference signal DIFF2 corresponding to the first phase difference P2 set as the target state for locking is activated and overlaps the duration in which the first difference signal DIFF1 is activated.

Specifically, as described with reference to FIG. 6A, the duration in which the first difference signal DIFF1 output from the first signal generation section 21 is activated to logic high overlaps the phase difference between the first clock CLK1 and the second clock CLK2.

In addition, as described with reference to FIG. 6A, the second difference signal DIFF2 output from the second signal generation section 22 maintains a deactivation state by an interval corresponding to the first phase difference P2 from the time point when it is deactivated from the activation state.

In the graph illustrated in FIG. 6B, the first phase difference P2 corresponding to one cycle of the 16-divided clock DCLK16 is in a target state for locking. Therefore, the change to a deactivation state of the second difference signal DIFF2 corresponding to the first phase difference P2 is behind the activation duration of the first difference signal DIFF1 by a certain duration ULS. That is, the time point when the second difference signal DIFF2 is deactivated from the activation state is in a state behind by duration ULS from the time point when the first difference signal DIFF1 is activated from the deactivation state.

Accordingly, it can be seen that the first unlock signal UNLOCK1, which is activated in response to the activation of the second difference signal DIFF2 is activated to logic high for the duration ULS, within the activation duration of the first difference signal DIFF1.

As described with reference to FIG. 6A, the third signal generation section 23 outputs the third difference signal DIFF3 by delaying the first difference signal DIFF1 by the delay amount corresponding to the second phase difference P3.

In such a case, the graph illustrated in FIG. 6B shows the length of the second phase difference P3 as longer than the target state for locking due to PVT variation. The duration in which the first difference signal DIFF1 is activated to logic high and the duration in which the third difference signal DIFF3 is activated to logic high do not overlap each other.

Accordingly, the second unlock signal UNLOCK2, which is activated in response to the activation of the third difference signal DIFF3 within the activation duration of the first difference signal DIFF1, is not activated to logic high and continuously maintains a logic low state.

In summary, in the graph illustrated in FIG. 6B, the second unlock signal UNLOCK2 is not activated to logic high and continuously maintains a logic low state, but the first unlock signal UNLOCK1 is activated to logic high for a duration ULS. Accordingly, the reset signal RST_LOCK is also activated to logic high in response to the activation of the first unlock signal UNLOCK1 to logic high for the duration ULS.

In this way, since the reset signal RST_LOCK is activated to logic high, the phase-locked loop determines that the phases of the first clock CLK1 and the second clock CLK2 are not synchronized.

FIG. 6C illustrates a phase-locked loop that has progressed past the state described with reference to FIG. 6B, where the phase difference SRP between the first clock CLK1 and the second clock CLK2 has been significantly narrowed compared to the graph of FIG. 6B.

In particular, FIG. 6C illustrates a state just before a locking determination is made, when the operation of the phase-locked loop is almost completed.

Specifically, as described with reference to FIG. 6A, the duration in which the first difference signal DIFF1 output from the first signal generation section 21 is activated to logic high overlaps the phase difference between the first clock CLK1 and the second clock CLK2.

In addition, as described with reference to FIG. 6A, the second difference signal DIFF2 output from the second signal generation section 22 maintains a deactivation state by an interval corresponding to the first phase difference P2 from the time point when it is deactivated from the activation state.

In such a case, the graph illustrated in FIG. 6C shows a state just before the locking determination is made, when the operation of the phase-locked loop is almost completed. Therefore, the deactivation state of the second difference signal DIFF2 corresponding to the first phase difference P2 is slightly ahead of the activation duration of the first difference signal DIFF1. That is, the time point when the second difference signal DIFF2 is deactivated from the activation state is slightly ahead of the time point when the first difference signal DIFF1 is activated from the deactivation state.

Accordingly, the first unlock signal UNLOCK1, which is activated in response to the activation of the second difference signal DIFF2 in the activation duration of the first difference signal DIFF1, is not activated to logic high and continuously maintains a logic low state.

As described with reference to FIG. 6A, the third signal generation section 23 outputs the third difference signal DIFF3 by delaying the first difference signal DIFF1 by the delay amount corresponding to the second phase difference P3.

In such a case, the graph illustrated in FIG. 6C shows the state just before the locking determination is made, when the operation of the phase-locked loop is almost completed. Therefore, it can be seen that the duration in which the first difference signal DIFF1 is activated to logic high and the duration in which the third difference signal DIFF3 is activated to logic high do not overlap each other.

Accordingly, the second unlock signal UNLOCK2, which is activated in response to the activation of the third differential signal DIFF3 in the activation duration of the first differential signal DIFF1, is not activated to logic high and continuously maintains a logic low state.

In summary, in the graph illustrated in FIG. 6C, each of the first unlock signal UNLOCK1 and the second unlock signal UNLOCK2 is not activated to logic high and continuously maintains a logic low state. Accordingly, the reset signal RST_LOCK is not also activated to logic high and continuously maintains a logic low state.

In this way, since the reset signal RST_LOCK is not activated to logic high, the phase-locked loop determines that the phases of the first clock CLK1 and the second clock CLK2 are synchronized.

The present disclosure described above is not limited by the aforementioned embodiment and the accompanying drawings, and it will be obvious to those skilled in the art to which the present disclosure pertains that various replacements, modifications, and changes can be made without departing from the technical spirit of the present disclosure.

For example, the position and the type of a logic gate and a transistor exemplified in the aforementioned embodiment should be differentially realized according to the polarity of an inputted signal.

What is claimed is:

1. A phase-locked loop comprising:
a phase detection unit configured to detect a phase difference between a first clock and a second clock;
a voltage generation unit configured to generate a control voltage in response to an output signal of the phase detection unit;
an oscillating unit configured to generate a third clock that toggles at a frequency corresponding to a level of the control voltage;
a clock division unit configured to generate a plurality of divided clocks by dividing the third clock at a plurality of ratios, and any one of the plurality of divided clocks that are output is selected as the second clock; and
a lock detection unit configured to generate a first unlock signal using the phase difference between the first and second clocks on the basis of a first phase difference corresponding to a cycle of a selected divided clock and to generate a second unlock signal using the phase difference between the first and second clocks on the basis of a second phase difference set by a plurality of delay cells.

2. The phase-locked loop of claim 1, wherein the lock detection unit activates the first unlock signal to a high logic state when the phase difference between the first clock and the second clock exceeds the first phase difference and maintains the first unlock signal at a low logic state when the phase difference between the first clock and the second clock does not exceed the first phase difference, and activates the second unlock signal to a high logic state when the phase difference between the first and second clocks exceeds the second phase difference and maintains the second unlock signal at a low logic state when the phase difference does not exceed the second phase difference.

3. The phase-locked loop of claim 2, wherein, when both the first and second unlock signals are deactivated to the low logic state and the first clock toggles a set number of times, the lock detection unit generates a lock completion signal indicating that the first clock and the second clock are synchronized.

4. The phase-locked loop of claim 1, wherein the lock detection unit comprises:
a first signal generation section configured to generate a first difference signal, in which a length of an activation duration is adjusted, in response to the output signal of the phase detection unit indicating the phase difference between the first and second clocks;
a second signal generation section configured to generate a second difference signal, in which a time point of a deactivation duration is adjusted, in response to an inversion clock of the selected divided clock among the plurality of divided clocks and a reference divided clock divided at a division rate twice higher than a division rate of the selected divided clock;
a third signal generation section configured to output a third difference signal by delaying the first difference signal by a delay amount set by the plurality of delay cells; and
a lock judgment section of the lock detection unit configured to combine activation or deactivation of the first and second unlock signals.

5. The phase-locked loop of claim 4, wherein the lock judgment section activates the first unlock signal in a duration in which activation states of the first difference signal and the second difference signal overlap each other, and
activates the second unlock signal in a duration in which activation states of the first difference signal and the third difference signal overlap each other.

6. The phase-locked loop of claim 5, wherein the lock judgment section comprises:
a reset signal output part configured to activate a reset signal in a duration in which any one of the first and second unlock signals is activated; and
a lock counting part configured to count the number of toggling of the first clock, to generate a lock completion signal indicating that the first clock and the second clock are synchronized when a counted value reaches a set number of times, and to initialize the counted value in response to the reset signal being activated.

7. The phase-locked loop of claim 4, wherein the clock division unit outputs, as the second clock, a clock divided at the highest ratio among the plurality of divided clocks, and
the lock detection unit selects, as the reference divided clock, a clock divided at a lower ratio than the second clock among the plurality of divided clocks.

8. A phase-locked loop comprising:
a phase detection unit configured to detect a phase difference between a first clock and a second clock;
a voltage generation unit configured to generate a control voltage in response to an output signal of the phase detection unit;
an oscillating unit configured to generate the second clock that toggles at a frequency corresponding to a level of the control voltage;
a clock division unit configured to generate a plurality of divided clocks by dividing the second clock at a plurality of ratios; and
a lock detection unit configured to generate a first unlock signal using the phase difference between the first and second clocks on the basis of a first phase difference corresponding to a cycle of a selected divided clock among the plurality of divided clocks, to generate a second unlock signal using the phase difference between the first and second clocks on the basis of a second phase difference set by a plurality of delay cells, and to generate a lock completion signal in response to the first and second unlock signals.

9. The phase-locked loop of claim 8, wherein the lock detection unit activates the first unlock signal by detecting when the phase difference between the first clock and the second clock exceeds the first phase difference, activates the second unlock signal by detecting when the phase difference exceeds the second phase difference, and the generated lock completion signal indicates that the lock has been completed when both the first and second unlock signals are deactivated.

10. The phase-locked loop of claim 9, wherein, when both the first and second unlock signals are deactivated while the first clock toggles a set number of times, the lock detection unit generates the lock completion signal that indicates that the lock has been completed.

11. The phase-locked loop of claim 8, wherein the lock detection unit comprises:
a first signal generation section configured to generate a first difference signal, in which a length of an activation duration is adjusted, in response to the output signal of the phase detection unit indicating the phase difference between the first and second clocks;
a second signal generation section configured to generate a second difference signal, in which a time point of a deactivation duration is adjusted, in response to an inversion clock of the selected divided clock among the plurality of divided clocks and a reference divided clock divided at a division rate twice higher than a division rate of the selected divided clock;
a third signal generation section configured to output a third difference signal by delaying the first difference signal by a delay amount set by the plurality of delay cells; and
a lock judgment section that activates the first unlock signal in response to the first and second difference signals, activates the second unlock signal in response to the first and third difference signals, and generates the lock completion signal using combination of activation or deactivation of the first and second unlock signals.

12. The phase-locked loop of claim 11, wherein the lock judgment section activates the first unlock signal in a duration in which activation states of the first difference signal and the second difference signal overlap each other, and
activates the second unlock signal in a duration in which activation states of the first difference signal and the third difference signal overlap each other.

13. The phase-locked loop of claim 12, wherein the lock judgment section comprises:
a reset signal output part configured to activate a reset signal in a duration in which any one of the first and second unlock signals is activated; and
a lock counting part configured to count the number of toggling of the first clock, to generate a signal indicating that a lock has been completed when a counted value reaches a set number of times, and to initialize the counted value in response to the reset signal being activated.

14. An operating method of a phase-locked loop, comprising:
generating a detection signal according to a result of detecting a phase difference between a first clock and a second clock;
generating a control voltage in response to the detection signal;
generating a third clock that toggles at a frequency corresponding to a level of the control voltage;
generating a plurality of divided clocks by dividing the third clock at a plurality of ratios and outputting any one of the plurality of divided clocks as the second clock;
activating a first unlock signal when the phase difference between the first and second clocks exceeds a first phase difference corresponding to a cycle of a selected divided clock among the plurality of divided clocks;
activating a second unlock signal when the phase difference between the first and second clocks exceeds a second phase difference set by a plurality of delay cells; and
generating a lock completion signal when both the first and second unlock signals are deactivated.

15. The operating method of a phase-locked loop of claim 14, wherein, when both the first and second unlock signals are deactivated while the first clock toggles a set number of times, the lock completion signal indicates that the first clock and the second clock are synchronized.
